(19) United States
(12) Patent Application Publication
(10) Pub. No.: US 2024/0237544 A1
(43) Pub. Date: Jul. 11, 2024

(54) VERTICAL MAGNETIC TUNNEL JUNCTION DEVICE

(71) Applicant: INTERNATIONAL BUSINESS MACHINES CORPORATION, ARMONK, NY (US)

(72) Inventors: Kevin W. Brew, Niskayuna, NY (US); Ching-Tzu Chen, Ossining, NY (US); Timothy Mathew Philip, Albany, NY (US); JIN PING HAN, Yorktown Heights, NY (US); Injo Ok, Albany, NY (US)

(21) Appl. No.: 18/150,816

(22) Filed: Jan. 6, 2023

(51) Int. Cl. H10N 50/10; H01L 23/528; H10N 50/01

(52) U.S. Cl. CPC H10N 50/10; H01L 23/5283; H10N 50/01

(57) ABSTRACT

Embodiments of present invention provide a vertical magnetic tunnel junction (MTJ) structure. The structure includes an L-shaped MTJ stack including an L-shaped reference layer conformally on an L-shaped performance enhancing layer; an L-shaped tunnel barrier layer conformally on the L-shaped reference layer; and an L-shaped free layer conformally on the L-shaped tunnel barrier layer, where a vertical portion of the L-shaped MTJ stack is adjacent to a sidewall of a metal stud, the metal stud being directly on top of a metal wire in a dielectric layer. The structure further includes a first and a second electrode contacting a horizontal portion and a vertical portion of the L-shaped MTJ stack. A method of forming the same is also provided.

### BACKGROUND

The present application relates to manufacturing of semiconductor integrated circuits. More particularly, it relates to method of forming a magnetic tunnel junction device and the structure formed thereby.

Magnetic tunnel junction (MTJ) devices with programable domain-walls have been proposed for applications in many advanced fields such as, for example, in analog artificial intelligence (AI) hardware. Generally, weights for the AI algorithm may be coded into the conductance of the MTJ devices. For example, by moving the location of the programable domain-wall in the free layer of the MTJ device, the conductance of the MTJ device may be tuned through a continuum of conductive values.

In the meantime, current MTJ devices are constructed laterally that take up a large footprint of real estate. In order to be applied, for example, in AI application which generally requires a large number of such MTJ devices, a new approach is needed that may be able to pack more MTJ devices into a fixed device area so as to increase density of the MTJ devices.

### SUMMARY

Embodiments of present invention provide a MTJ structure. The MTJ structure includes at least one MTJ device. The MTJ device includes an L-shaped MTJ stack, the L-shaped MTJ stack including an L-shaped reference layer; an L-shaped tunnel barrier layer conformally on the L-shaped reference layer; and an L-shaped free layer conformally on the L-shaped tunnel barrier layer, where a vertical portion of the L-shaped MTJ stack is adjacent to a sidewall of a metal stud, the metal stud being directly on top of a metal wire in a dielectric layer. By forming the MTJ stack of the MTJ device in an L-shaped form, the MTJ device may occupy less real estate in a device area, enabling more MTJ devices to be formed in the same device area.

In one embodiment, the L-shaped MTJ stack further includes an L-shaped performance enhancing layer with the L-shaped reference layer being conformally on the L-shaped performance enhancing layer, and the MTJ device further includes an L-shaped spin-orbit coupling layer conformally on the L-shaped free layer and an L-shaped capping layer conformally on the L-shaped spin-orbit coupling layer. The use of the spin-orbit coupling layer helps reduce the threshold of current for driving the domain-wall in the L-shaped free layer, thereby enhancing the MTJ device performance.

In another embodiment, the MTJ device further includes a first electrode being in contact with a horizontal portion of the L-shaped capping layer; a conductive stair being horizontally in contact with a vertical portion of the L-shaped capping layer; and a second electrode being in contact with the vertical portion of the L-shaped capping layer through the conductive stair. The first and second electrodes may be used in programing the MTJ device by driving the domain-wall to a proper location.

In one embodiment, the MTJ device is a first MTJ device and the metal stud is a first metal stud, and the MTJ structure further includes a second MTJ device, the second MTJ device including an L-shaped MTJ stack that, from a bottom to a top thereof, includes an L-shaped performance enhancing layer, an L-shaped reference layer, an L-shaped tunnel barrier layer; and an L-shaped free layer; and an L-shaped spin-orbit coupling layer and an L-shaped capping layer on top of the L-shaped MTJ stack of the second MTJ device, where a vertical portion of the L-shaped MTJ stack of the second MTJ device is adjacent to a sidewall of a second metal stud, the second metal stud being separated from the first metal stud. Multiple MTJ devices such as the first and second MTJ devices may be used together to reduce variance in the domain-wall locations of the MTJ structure or, alternatively, may be used as separate MTJ devices.

In one embodiment, the sidewall of the first metal stud is a first sidewall of the first metal stud, and the MTJ structure further includes a third MTJ device, the third MTJ device including an L-shaped MTJ stack that, from a bottom to a top thereof, includes an L-shaped performance enhancing layer, an L-shaped reference layer, an L-shaped tunnel barrier layer; and an L-shaped free layer; and an L-shaped spin-orbit coupling layer and an L-shaped capping layer on top of the L-shaped MTJ stack of the third MTJ device, where a vertical portion of the L-shaped MTJ stack of the third MTJ device is adjacent to a second sidewall of the first metal stud, the second sidewall being opposite to the first sidewall of the first metal stud. The first and third MTJ devices may be formed adjacent to the same metal stud sharing a same metal wire underneath the metal stud which serves as a third electrode to the first and third MTJ devices.

In one embodiment, the third MTJ device further includes a first electrode in contact with a horizontal portion of the L-shaped capping layer of the third MTJ device and a second electrode in contact with a vertical portion of the L-shaped capping layer of the third MTJ device, the first electrodes of the first MTJ device and the third MTJ device are connected to a first power source, and the second electrodes of the first MTJ device and the third MTJ device are connected to a second power source. According to one embodiment, the first and third MTJ devices are connected in parallel to help reduce variance in the domain-wall location.

In another embodiment, the second metal stud being directly on top of the metal wire in the dielectric layer; where the second MTJ device further includes a first electrode in contact with a horizontal portion of the L-shaped capping layer of the second MTJ device and a second electrode in contact with a vertical portion of the L-shaped capping layer of the second MTJ device; and where the first electrodes of the first MTJ device and the second MTJ device are connected to a first power source and the second electrodes of the first MTJ device and the second MTJ device are connected to a second power source. According to one embodiment, the first and second MTJ devices are connected in parallel to help reduce variance in the domain-wall location, where they share a same metal wire, underneath both the first and the second metal stud, that may serve as a third electrode.

In a further embodiment, the metal wire in the dielectric layer is a first metal wire, and where the second metal stud is directly on top of a second metal wire in the dielectric layer, the second metal wire being separated from the first metal wire; wherein the second MTJ device further includes a first electrode in contact with a horizontal portion of the L-shaped capping layer of the second MTJ device and a second electrode in contact with a vertical portion of the L-shaped capping layer of the second MTJ device; and where the first electrode of the first MTJ device is connected to a first power source, the second electrode of the first MTJ device is connected to a second power source, the first electrode of the second MTJ device is connected to a third power source, and the second electrode of the second MTJ device is connected to a fourth power source, where the first, second, third, and fourth power sources are different power sources. The metal wire may be etched into one or more separate and/or independent metal wires that serve to form one or more separate and/or independent MTJ devices.

Embodiments of present invention also provide a method of forming a magnetic tunnel junction (MTJ) structure. The method includes forming a raw metal stud on top of a metal wire, the metal wire being embedded in a dielectric layer; forming a blanket MTJ stack over the raw metal stud and the dielectric layer; removing a top portion of the blanket MTJ stack to expose a top surface of the raw metal stud thereby forming an L-shaped raw MTJ stack adjacent the raw metal stud; forming a first set of one or more MTJ devices by dividing the raw metal stud into one or more metal studs and dividing the L-shaped raw MTJ stack into one or more L-shaped MTJ stacks adjacent to a first sidewall of the one or more metal studs; forming a first electrode of the first set of one or more MTJ devices, the first electrode contacting a horizonal portion of the one or more L-shaped MTJ stacks; and forming a second electrode of the first set of one or more MTJ devices, the second electrode contacting a vertical portion of the one or more L-shaped MTJ stacks.

In one embodiment, the method further includes forming a second set of one or more MTJ devices by dividing the L-shaped raw MTJ stack into one or more L-shaped MTJ stacks adjacent to a second sidewall of the one or more metal studs, the second sidewall being opposite to the first sidewall; forming a third electrode of the second set of one or more MTJ devices, the third electrode contacting a horizonal portion of the one or more L-shaped MTJ stacks at the second sidewall of the one or more metal studs; and forming a fourth electrode of the second set of one or more MTJ devices, the fourth electrode contacting a vertical portion of the one or more L-shaped MTJ stacks at the second sidewall of the one or more metal studs.

In another embodiment, the method further includes forming a first power source connecting to the first electrode of the first set of one or more MTJ devices and the third electrode of the second set of one or more MTJ devices; and forming a second power source connecting to the second electrode of the first set of one or more MTJ devices and the fourth electrode of the second set of one or more MTJ devices.

In yet another embodiment, the method further includes dividing the metal wire embedded in the dielectric layer into one or more metal wires corresponding to the one or more metal studs on top thereof; forming a first and a second power source connecting to the first and the second electrode of a first MTJ device of the first set of one or more MTJ devices; and forming a third and a fourth power source connecting to the first and the second electrode of a second MTJ device of the first set of one or more MTJ devices, wherein the first power source is different from the third power source and the second power source is different from the fourth power source.

In one embodiment, each of the L-shaped MTJ stacks includes an L-shaped free layer over an L-shaped tunnel barrier layer over an L-shaped reference layer and over an L-shaped performance enhancing layer, and the method further includes forming an L-shaped spin-orbit coupling (SOC) layer over each of the L-shaped MTJ stacks and an L-shaped capping layer over the L-shaped SOC layer.

In another embodiment, the method further includes forming a conductive stair horizontally in contact with a vertical portion of the L-shaped capping layer, wherein the second electrode is in contact with the conductive stair.

### BRIEF DESCRIPTION OF THE DRAWINGS

The present invention will be understood and appreciated more fully from the following detailed description of embodiments of present invention, taken in conjunction with accompanying drawings of which:

FIGS. 1A, 1B to FIGS. 12A, 12B are demonstrative illustrations of cross-sectional views and top views of a MTJ structure in a process of manufacturing thereof according to one embodiment of present invention;

FIGS. 13A, 13B is a demonstrative illustration of cross-sectional view and top view of a MTJ structure in a process of manufacturing thereof according to another embodiment of present invention; and

FIG. 14 is a demonstrative illustration of a flow-chart of a method of manufacturing a MTJ structure according to one embodiment of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

To provide spatial context to different structural orientations of the semiconductor structures shown in the drawings, XYZ Cartesian coordinates may be provided in some of the drawings. The terms “vertical” or “vertical direction” or “vertical height” as used herein denote a Z-direction of the Cartesian coordinates shown in the drawings, and the terms “horizontal” or “horizontal direction” or “lateral direction” as used herein denote an X-direction and/or a Y-direction of the Cartesian coordinates shown in the drawings.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

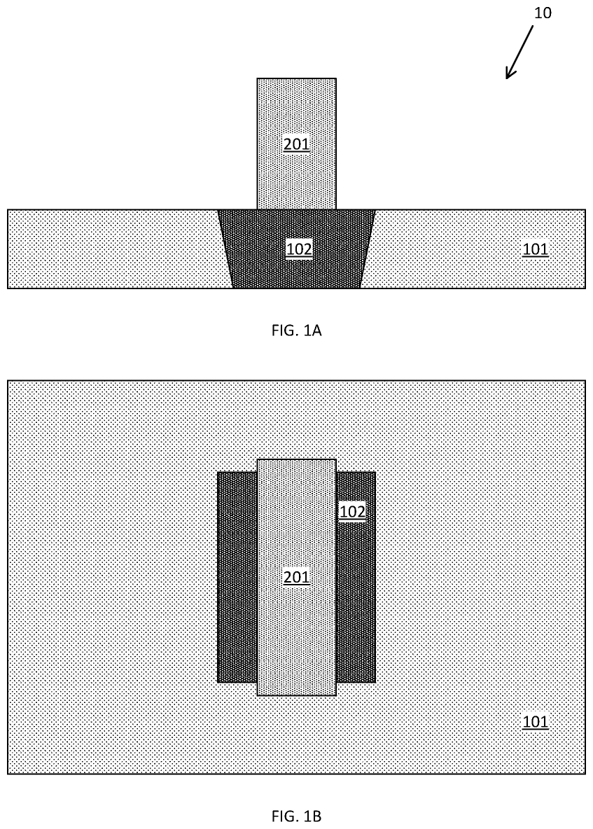

FIGS. 1A and 1B are demonstrative illustrations of a cross-sectional view (A) and a top view (B) of a vertical MTJ structure in a step of manufacturing thereof according to one embodiment of present invention. More particularly, in forming a vertical MTJ structure 10, embodiments of present invention provide forming a metal wire 102, such as a conductive bar, in a supporting structure such as a dielectric layer 101. Alternatively, embodiments of present invention provide receiving a dielectric layer 101 with a metal wire 102 formed therein. In one embodiment, the dielectric layer 101 may be an interlevel dielectric (ILD) layer of, for example, silicon-oxide or silicon-nitride material and may be formed on top of a semiconductor substrate (not shown). On the other hand, the metal wire 102 may be made of, for example, tantalum-nitride (TaN), titanium-nitride (TiN), copper (Cu), tungsten (W), or other suitable conductive materials. The metal wire 102 may serve as an electrode (such as a third electrode) of one or more MTJ devices of the vertical MTJ structure 10. In some embodiments, the metal wire 102 may be a plurality of metal wires or may be divided into a plurality of metal wires, as being described below in more details, and the plurality of metal wires serve as independent electrodes of one or more MTJ devices of the vertical MTJ structure 10.

Embodiments of present invention further provide forming a raw metal stud 201, such as a raw metal fin or raw metal bar, directly on top of the metal wire 102. The raw metal stud 201 may be made of, for example, TaN, TiN, Cu, W, or other suitable conductive materials and may be formed through, for example, a substrative etch process of a metal layer. The raw metal stud 201 may be centrally aligned with the metal wire 102.

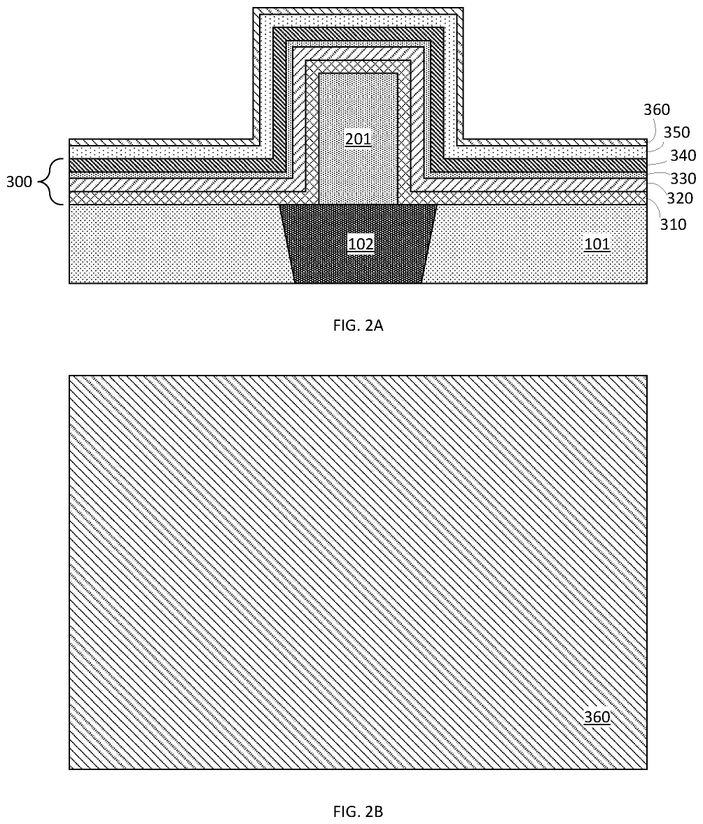

FIGS. 2A and 2B are demonstrative illustrations of a cross-sectional view (A) and a top view (B) of a vertical MTJ structure in a step of manufacturing thereof according to one embodiment of present invention. More particularly, following the step illustrated in FIGS. 1A and 1B, embodiments of present invention provide forming a raw blanket MTJ stack 300 over and covering the raw metal stud 201 and the dielectric layer 101. More specifically, forming the raw blanket MTJ stack 300 may include, through a chemical vapor deposition (CVD) process, an atomic layer deposition (ALD) process, or a physical vapor deposition (PVD) process, forming a raw blanket conformal performance enhancing layer 310 on or over the raw metal stud 201 and a top surface of the dielectric layer 101; a raw blanket conformal reference layer 320 on or over the raw blanket conformal performance enhancing layer 310; a raw blanket conformal tunnel barrier layer 330 on or over the raw blanket conformal reference layer 320; and a raw blanket conformal free layer 340 on or over the raw blanket conformal tunnel barrier layer 330.

After forming the raw blanket MTJ stack 300 which includes the raw blanket conformal performance enhancing layer 310, the raw blanket conformal reference layer 320, the raw blanket conformal tunnel barrier layer 330, and the raw blanket conformal free layer 340, embodiments of present invention further provide forming a raw blanket conformal spin-orbit coupling (SOC) layer 350 on or over the raw blanket MTJ stack 300 and forming a raw blanket conformal capping layer 360 on or over the raw blanket conformal SOC layer 350.

In one embodiment, the raw blanket conformal reference layer 320 and the raw blanket conformal free layer 340 may be blanket ferromagnetic layers. Each blanket ferromagnetic layer may be independently a layer of cobalt (Co), iron (Fe), and boron (B) based material (CoFeB) such as, for example, an alloy of Co, Fe, and B although other types of ferromagnetic material such as an alloy of Co and Fe (CoFe) or an alloy of nickel (Ni) and Fe (NiFe) may be used as well. The raw blanket conformal reference layer 320 and the raw blanket conformal free layer 340 may be formed to have a thickness that individually ranges from about 0.5 nm to about 30 nm.

In one embodiment, the raw blanket conformal tunnel barrier layer 330 may be a layer of magnesium oxide (MgO) or other suitable materials including, for example, aluminum oxide

(Al₂O₃) or titanium oxide (TiO₂) and may be formed to have a thickness typically ranging from about 0.5 nm to about 1.5 nm although other thicknesses are possible as well.

In one embodiment, the raw blanket conformal SOC layer 350 may be a layer of spin-orbit torque material that may include, for example, tantalum (Ta), platinum (Pt), tungsten (W), tungsten oxide (WOx), topological insulators (such as Bi2Se3, Sb2Te3, BixSby, BixSb1-xTey), topological semimetals (such as WTe2, TaAs, NbAs, TaP, NbP, Co2MnGa), ferrimagnets (such as FexTby, MnxPdy, IrxMny), transition metal oxides (such as SrIrO3) IrO2, BaPb1-xBixO3), heavy fermion materials (such as YbAl), or other suitable materials. The raw blanket conformal SOC layer 350 may be formed to have a thickness typically ranging from about 0.5 nm to about 5 nm. The raw blanket conformal capping layer 360 may be a layer of ruthenium (Ru) or other suitable materials. The raw blanket conformal capping layer 360 protects the underneath layers such as the raw blanket conformal SOC layer 350 from oxidation while remaining to be conductive even when itself is being oxidized to become ruthenium-oxide.

In one embodiment, the raw blanket conformal performance enhancing layer 310 may be a pinning layer, a magnetic compensation layer, or a combination of a pinning layer and a magnetic compensation layer. For example, the raw blanket conformal performance enhancing layer 310 may be a synthetic anti-ferromagnetic (SAF) layer. In a MTJ device, a performance enhancing layer may enhance the MTJ device performance by, for example, pinning the magnetization of a reference layer through exchange coupling and providing certain magnetic field compensation.

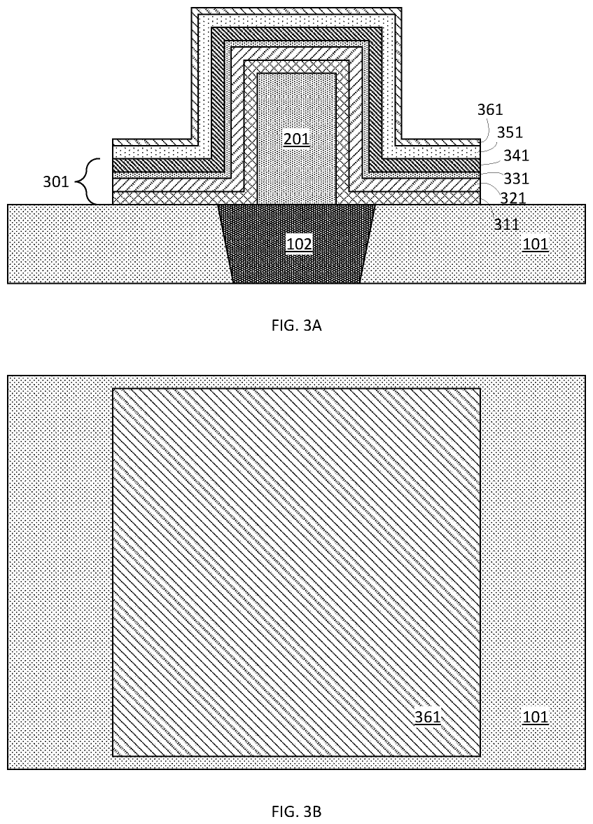

FIGS. 3A and 3B are demonstrative illustrations of a cross-sectional view (A) and a top view (B) of a vertical MTJ structure in a step of manufacturing thereof according to one embodiment of present invention. More particularly, following the step illustrated in FIGS. 2A and 2B, embodiments of present invention provide patterning the raw blanket conformal capping layer 360 into a blanket conformal capping layer 361; patterning the raw blanket conformal SOC layer 350 into a blanket conformal SOC layer 351; and patterning the raw blanket MTJ stack 300 into a blanket MTJ stack 301. The blanket MTJ stack 301 may include a blanket conformal performance enhancing layer 311, a blanket conformal reference layer 321 on the blanket conformal performance enhancing layer 311, a blanket conformal tunnel barrier layer 331 on the blanket conformal reference layer 321, and a blanket conformal free layer 341 on the blanket conformal tunnel barrier layer 331.

The patterning may be made through a selective etching process and the blanket conformal capping layer 361, the blanket conformal SOC layer 351, the blanket conformal free layer 341, the blanket conformal tunnel barrier layer 331, the blanket conformal reference layer 321, and the blanket conformal performance enhancing layer 311 may be substantially vertically aligned at their respective vertical edges.

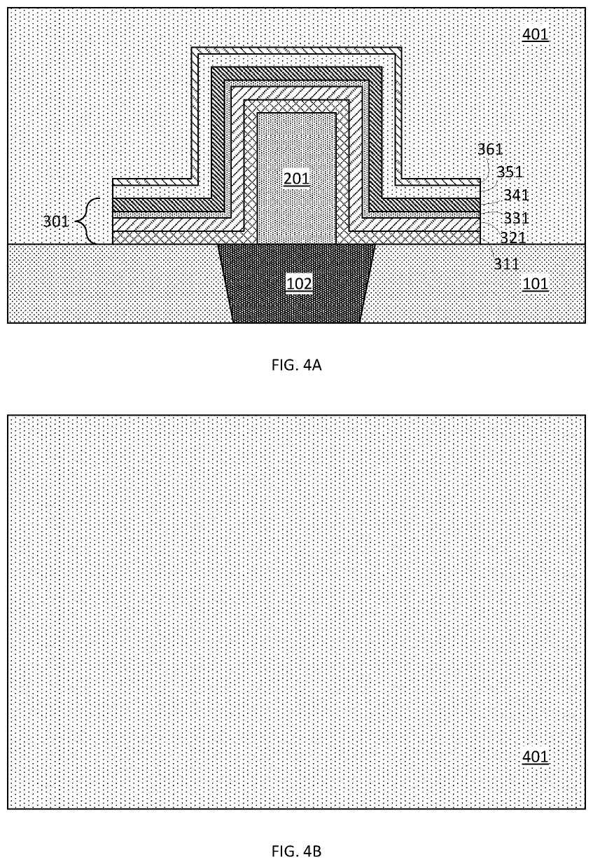

FIGS. 4A and 4B are demonstrative illustrations of a cross-sectional view (A) and a top view (B) of a vertical MTJ structure in a step of manufacturing thereof according to one embodiment of present invention. More particularly, following the step illustrated in FIGS. 3A and 3B, embodiments of present invention provide forming a dielectric layer 401 over and above the blanket conformal capping layer 361, the blanket conformal SOC layer 351, and the blanket MTJ stack 301; and over and above the exposed top surface of the dielectric layer 101. In one embodiment, the dielectric layer 401 may be a layer of organic planarization layer (OPL) and the OPL may be formed in preparation for the opening of a top surface of the raw metal stud 201 as being described below in more details.

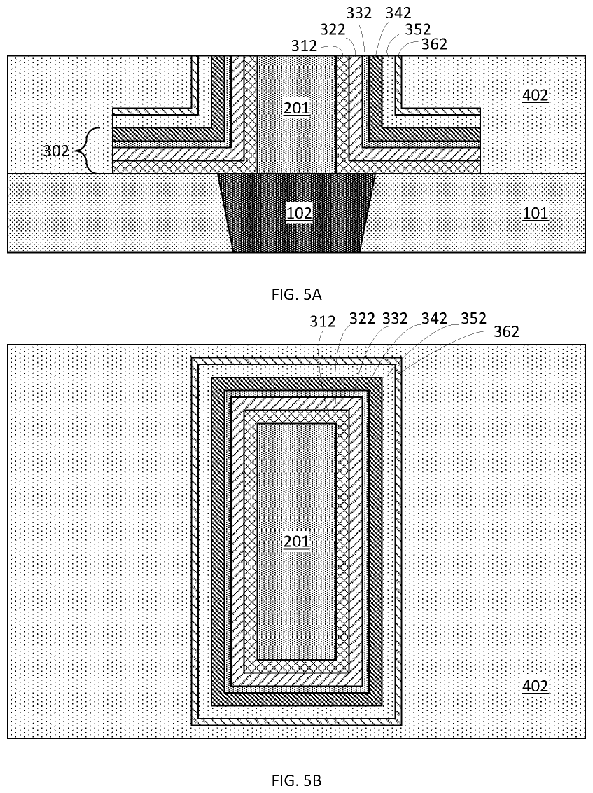

FIGS. 5A and 5B are demonstrative illustrations of a cross-sectional view (A) and a top view (B) of a vertical MTJ structure in a step of manufacturing thereof according to one embodiment of present invention. More particularly, following the step illustrated in FIGS. 4A and 4B, embodiments of present invention provide exposing the top surface of the raw metal stud 201 by recessing the dielectric layer 401; by removing the top portion and a portion of the vertical portion of the blanket conformal capping layer 361, the blanket conformal SOC layer 351, and the blanket MTJ stack 301 until the top surface of the raw metal stud 201 is exposed.

In one embodiment, the top surface of the raw metal stud 201 may be exposed through, for example, a chemical-mechanic-polishing (CMP) process. The CMP process may recess the dielectric layer 401 to create a dielectric layer 402, and may create or produce an L-shaped raw MTJ stack 302 that includes an L-shaped raw performance enhancing layer 312, an L-shaped raw reference layer 322 on the L-shaped raw performance enhancing layer 312, an L-shaped raw tunnel barrier layer 332 on the L-shaped raw reference layer 322, and an L-shaped raw free layer 342 on the L-shaped raw tunnel barrier layer 332. The CMP process may also create or produce an L-shaped raw SOC layer 352 on the L-shaped raw MTJ stack 302, and an L-shaped raw capping layer 362 on the L-shaped raw SOC layer 352. The L-shaped raw capping layer 362 and vertical edges of the L-shaped raw SOC layer 352 and the L-shaped raw MTJ stack 302 may be surrounded by or embedded in the dielectric layer 402. Here an “L-shaped” structure means a structure that has a vertical portion and a horizontal portion, and the vertical portion stands at an edge, either a right edge or a left edge, of the horizontal portion of the structure. For example, an L-shaped layer includes a vertical portion of a layer that stands at an edge of a horizontal portion of the layer.

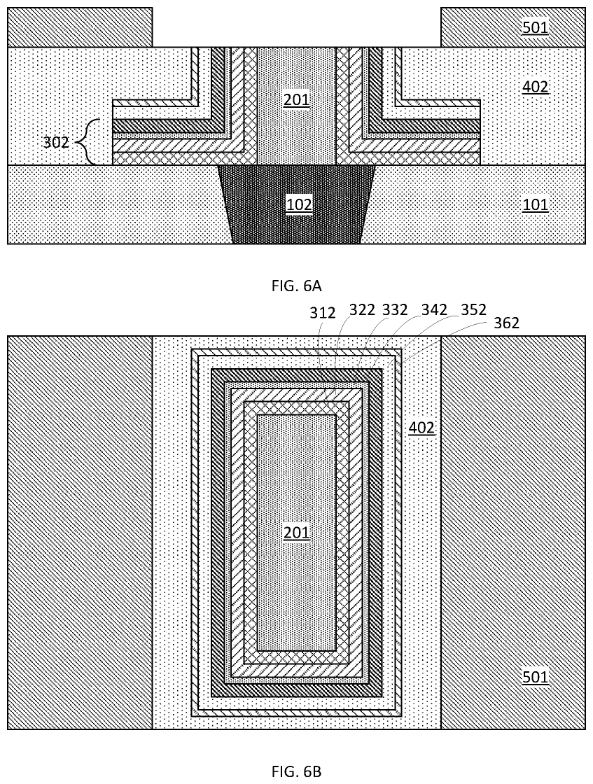

FIGS. 6A and 6B are demonstrative illustrations of a cross-sectional view (A) and a top view (B) of a vertical MTJ structure in a step of manufacturing thereof according to one embodiment of present invention. More particularly, following the step illustrated in FIGS. 5A and 5B, embodiments of present invention may proceed to form a raw conductive stair that contacts a vertical portion of the L-shape raw capping layer 362. In order to forming the raw conductive stair, embodiments of present invention provide forming a hard mask 501 on top of the dielectric layer 402. The hard mask 501 exposes a portion of the dielectric layer 402 that surrounds the vertical portion of the L-shaped raw capping layer 362.

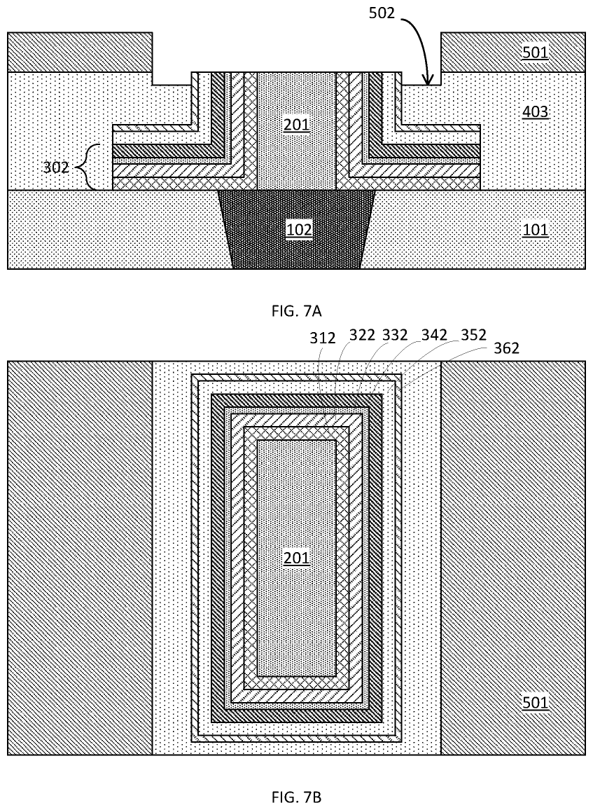

FIGS. 7A and 7B are demonstrative illustrations of a cross-sectional view (A) and a top view (B) of a vertical MTJ structure in a step of manufacturing thereof according to one embodiment of present invention. More particularly, following the step illustrated in FIGS. 6A and 6B, embodiments of present invention provide selectively recessing the exposed portion of the dielectric layer 402 thereby creating or producing a recess 502 that exposes an upper portion of the vertical portion of the L-shaped raw capping layer 362, and transforming the dielectric layer 402 into a dielectric layer 403. The dielectric layer 403 surrounds the recess 502.

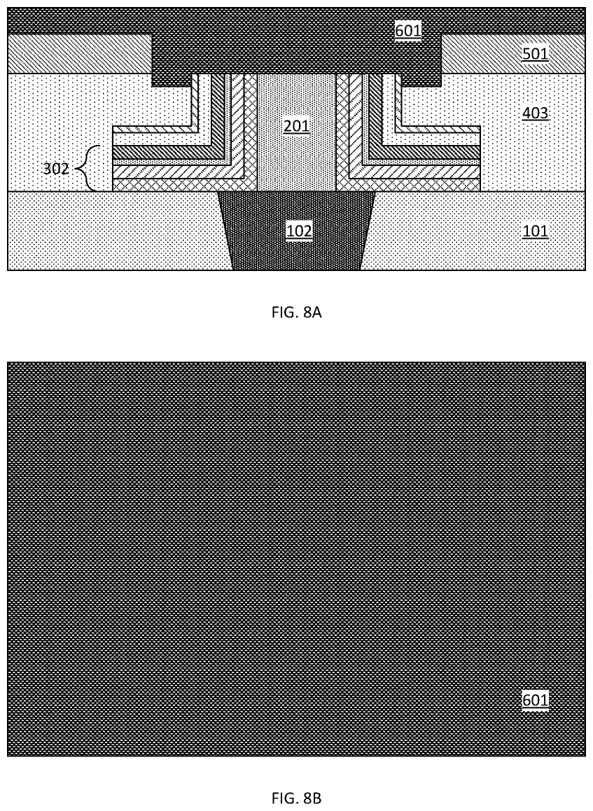

FIGS. 8A and 8B are demonstrative illustrations of a cross-sectional view (A) and a top view (B) of a vertical MTJ structure in a step of manufacturing thereof according to one embodiment of present invention. More particularly, following the step illustrated in FIGS. 7A and 7B, embodiments of present invention provide filling the recess 502 with a conductive material by forming a conductive material layer 601 through deposition in the recess 502, above the top surface of the raw metal stud 201, and above the hard mask 501.

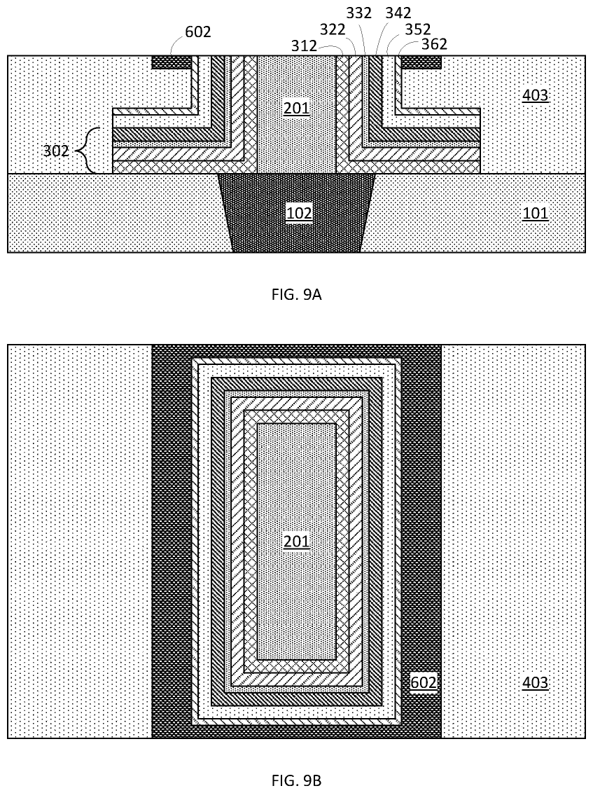

FIGS. 9A and 9B are demonstrative illustrations of a cross-sectional view (A) and a top view (B) of a vertical MTJ structure in a step of manufacturing thereof according to one embodiment of present invention. More particularly, following the step illustrated in FIGS. 8A and 8B, embodiments of present invention provide applying a planarization process, such as a CMP process, to remove portions of the conductive material layer 601 that are above the recess 502 and above the top surface of the raw metal stud 201. The planarization process may also remove the hard mask 501 and create or produce a raw conductive stair 602 in the recess 502. The raw conductive stair 602 may be made coplanar with the top surface of the raw metal stud 201 and may be in contact with, by surrounding, the upper portion of the vertical portion of the L-shaped raw capping layer 362. As a result, the raw conductive stair 602 may be electrically connected to a vertical portion of the L-shaped raw MTJ stack 302 through the L-shaped raw capping layer 362 and the L-shaped raw SOC layer 352, both of which are conductive. The raw conductive stair 602 may be surrounded by and embedded in the dielectric layer 403.

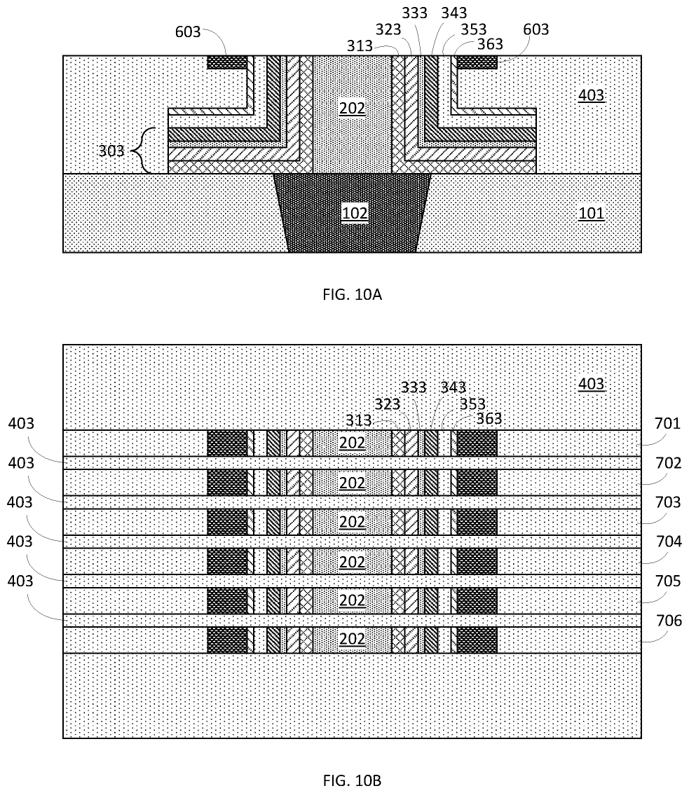

FIGS. 10A and 10B are demonstrative illustrations of a cross-sectional view (A) and a top view (B) of a vertical MTJ structure in a step of manufacturing thereof according to one embodiment of present invention. More particularly, following the step illustrated in FIGS. 9A and 9B, embodiments of present invention provide, through an ion-beam-etch (IBE) process for example, dividing or etching the raw metal stud 201 into one or more metal studs 202 that are separated and independent, and dividing or etching the L-shaped raw MTJ stack 302 into one or more L-shaped MTJ stacks 303 directly adjacent to the corresponding one or more metal studs 202. Embodiments of present invention further provide dividing or etching the L-shaped raw SOC layer 352 and the L-shaped raw capping layer 362 into one or more L-shaped SOC layers 353 and one or more L-shaped capping layers 363 covering the corresponding one or more L-shaped MTJ stacks 303, and dividing or etching the raw conductive stair 602 into one or more conductive stairs 603 that are horizontally in contact with a vertical portion of an L-shaped capping layer 363. Embodiments of present invention thereby provide forming one or more MTJ device pairs 701, 702, 703, 704, 705, and 706. In other words, embodiments of present invention provide forming a first set of one or more MTJ devices at a first side (e.g., left side) of the one or more metal studs 202 and a second set of one or more MTJ devices at a second side (e.g., right side) of the one or more metal studs 202. The one or more metal studs 202 are horizontally aligned since they are made from the same raw metal stud 201 but are separated. For example, the one or more studs 202 may be separated by a dielectric layer 403 as being described below in more details.

Each of the one or more MTJ device pairs, such as a MTJ device pair 701, may include a first MTJ device at a first side of the metal stud 202 and a second MTJ device at a second side of the metal stud 202. A vertical portion of the L-shaped MTJ stack 303 of the first MTJ device is adjacent to a first sidewall, e.g., a left sidewall, of the metal stud 202 and a vertical portion of the L-shaped MTJ stack 303 of the second MTJ device is adjacent to a second sidewall, e.g., a right sidewall, of the metal stud 202. The first sidewall, e.g., the left sidewall, of the metal stud 202 is opposite the second sidewall, e.g., the right sidewall, of the metal stud 202.

In dividing or etching the L-shaped raw MTJ stack 302 into the one or more L-shaped MTJ stacks 303, embodiments of present invention further provide dividing or etching the L-shaped raw performance enhancing layer 312 into one or more L-shaped performance enhancing layers 313; dividing or etching the L-shaped raw reference layer 322 into one or more L-shaped reference layers 323; dividing or etching the L-shaped raw tunnel barrier layer 332 into one or more L-shaped tunnel barrier layers 333; and dividing or etching the L-shaped raw free layer 342 into one or more L-shaped free layers 343.

After etching the raw metal stud 201, the L-shaped raw MTJ stack 302, and the L-shaped raw SOC layer 352 and the L-shaped raw capping layer 362, embodiments of present invention provide back-filling gaps between the one or more MTJ device pairs 701, 702, 703, 704, 705, and 706 with a dielectric material such as that of the dielectric layer 403.

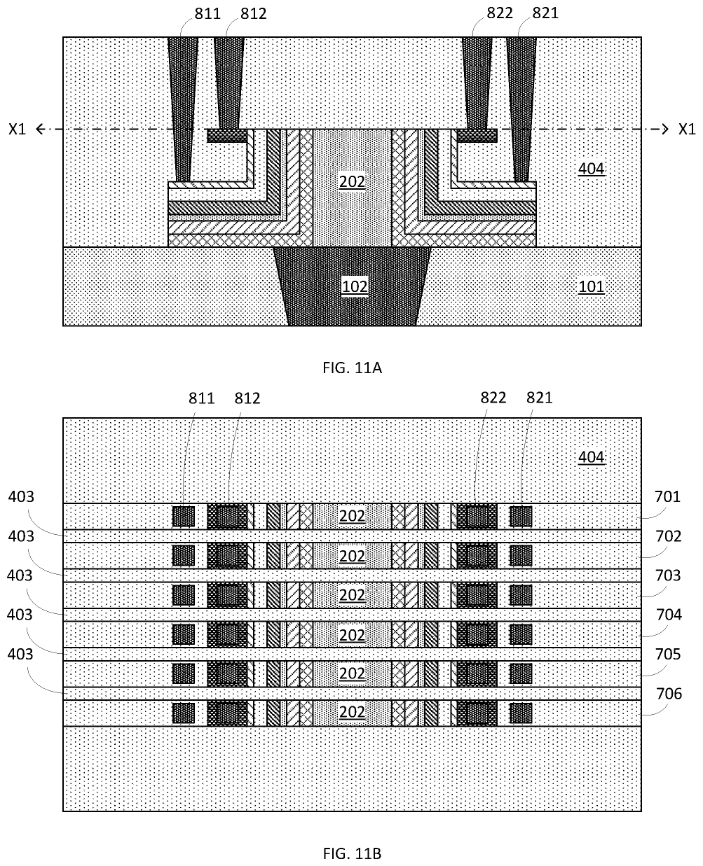

FIG. 11A is a demonstrative illustration of a cross-sectional view and FIG. 11B is a demonstrative illustration of a top view, at a cross-section X1-X1, of a vertical MTJ structure in a step of manufacturing thereof according to one embodiment of present invention. More particularly, following the step illustrated in FIGS. 10A and 10B, embodiments of present invention provide depositing additional dielectric material on top of the dielectric layer 403 to form a dielectric layer 404; forming a first electrode 811 through the dielectric layer 404 to be in contact with a horizontal portion of the L-shaped capping layers 363 of the first set of MTJ devices at the first side of the one or more metal studs 202; and forming a second electrode 812 through the dielectric layer 404 to be in contact with a vertical portion of the L-shaped capping layers 363, via the conductive stairs 603, of the first set of MTJ devices at the first side of the one or more metal stud 202.

Embodiments of present invention further provide forming a first electrode 821 through the dielectric layer 404 to be in contact with a horizontal portion of the L-shaped capping layers 363 of the second set of MTJ devices at the second side of the one or more metal studs 202; and forming a second electrode 822 through the dielectric layer 404 to be in contact with a vertical portion of the L-shaped capping layers 363, via the conductive stairs 603, of the second set of MTJ devices at the second side of the one or more metal studs 202.

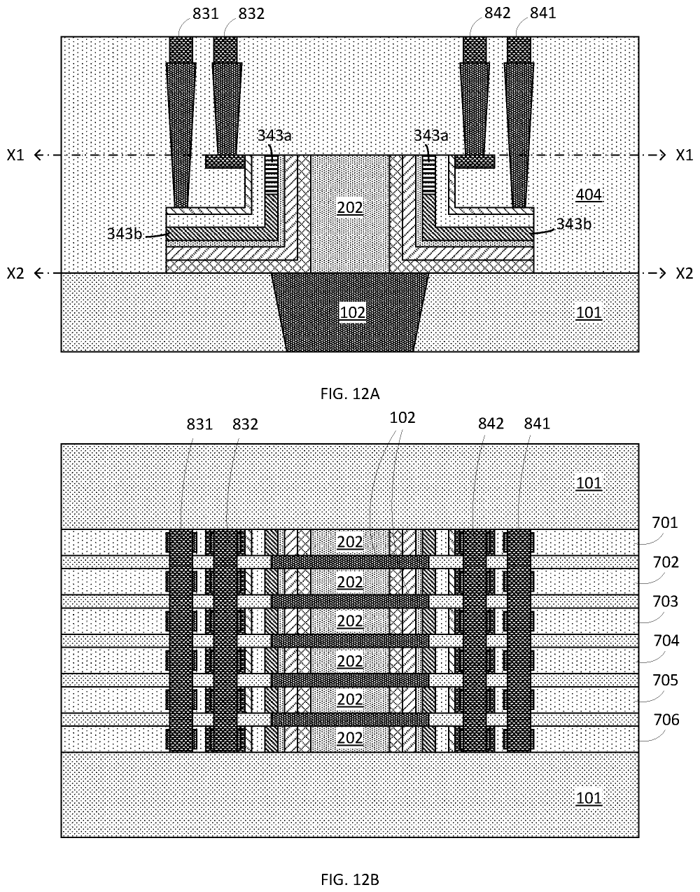

FIGS. 12A and 12B are demonstrative illustrations of a cross-sectional view (A) and a top view (B) of a vertical MTJ structure in a step of manufacturing thereof according to one embodiment of present invention. Additionally, for the purpose of explanation, FIG. 12B also illustrates a partial top view, at a cross-section X1-X1, of the MTJ device pairs 701, 702, 703, 704, 705, and 706 and a partial top view, at a cross-section X2-X2, of gaps between the MTJ device pairs 701, 702, 703, 704, 705, and 706.

More particularly, following the step illustrated in FIGS. 11A and 11B, embodiments of present invention provide forming a first power source 831 connecting the first electrodes 811 of each of the first set of MTJ devices at the first side of the one or more metal studs 202, and a second power source 832 connecting the second electrodes 812 of each of the first set of MTJ devices at the first side of the one or more metal studs 202. Embodiments of present invention further provide forming a first power source 841 connecting the first electrodes 821 of each of the second set of MTJ devices at the second side of the one or more metal studs 202, and a second power source 842 connecting the second electrodes 822 of each of the second set of MTJ devices at the second side of the one or more metal studs 202. In one embodiment, the first power source 831 and the first power source 841 are a same first power source, and the second power source 832 and the second power source 842 are a same second power source. In the above embodiment, there is the metal wire 102 underneath the one or more metal studs 202 and the metal wire 102 serves as a third electrode of the MTJ device pairs 701, 702, 703, 704, 705, and 706.

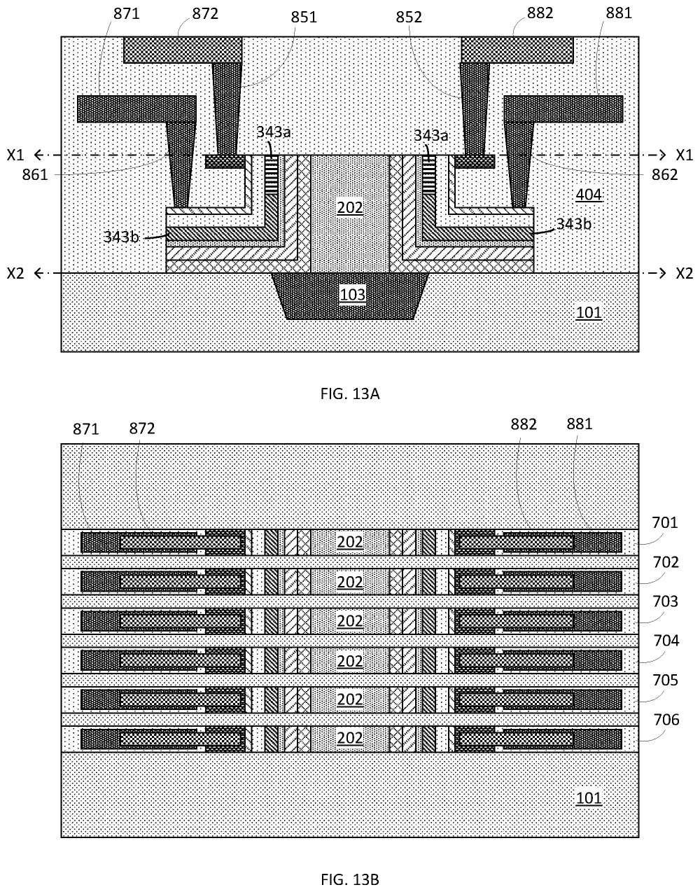

FIGS. 13A and 13B are demonstrative illustrations of a cross-sectional view (A) and a top view (B) of a vertical MTJ structure in a step of manufacturing thereof according to one embodiment of present invention. Additionally, for the purpose of explanation, FIG. 13B also illustrates a partial top view, at a cross-section X1-X1, of the MTJ device pairs 701, 702, 703, 704, 705, and 706 and a partial top view, at a cross-section X2-X2, of gaps between the MTJ device pairs 701, 702, 703, 704, 705, and 706.

More particularly, following the step illustrated in FIGS. 11A and 11B, embodiments of present invention provide forming a first power source 871 connecting to the first electrode 811 of each of the first set of MTJ devices individually at the first side of the one or more metal studs 202; and forming a second power source 872 connecting to the second electrode 812 of each of the first set of MTJ devices individually at the first side of the one or more metal studs 202. Embodiments of present invention further provide forming a third power source 881 connecting to the first electrode 821 of each of the second set of MTJ devices individually at the second side of the one or more metal studs 202; and forming a fourth power source 882 connecting to the second electrode 822 of each of the second set of MTJ devices individually at the second side of the one or more metal studs 202. In the above embodiment, portions of the metal wire 102 in the gaps are removed or etched away. In other words, the metal wire 102 is divided into one or more metal wires 103 underneath each of the one or more metal studs 202.

Here, both in FIG. 12A and in FIG. 13A, the L-shaped free layers 343 are demonstratively illustrated to include a first portion 343a and a second portion 343b, illustrating a domain-wall position at the interface between the first portion 343a and the second portion 343b of the L-shaped free layers 343. The position of the domain-wall may be moved or influenced by voltage difference between the first and second power sources 831 and 832, between the first and second power sources 841 and 842, between the first and second power sources 871 and 872, and/or between the third and fourth power sources 881 and 882.

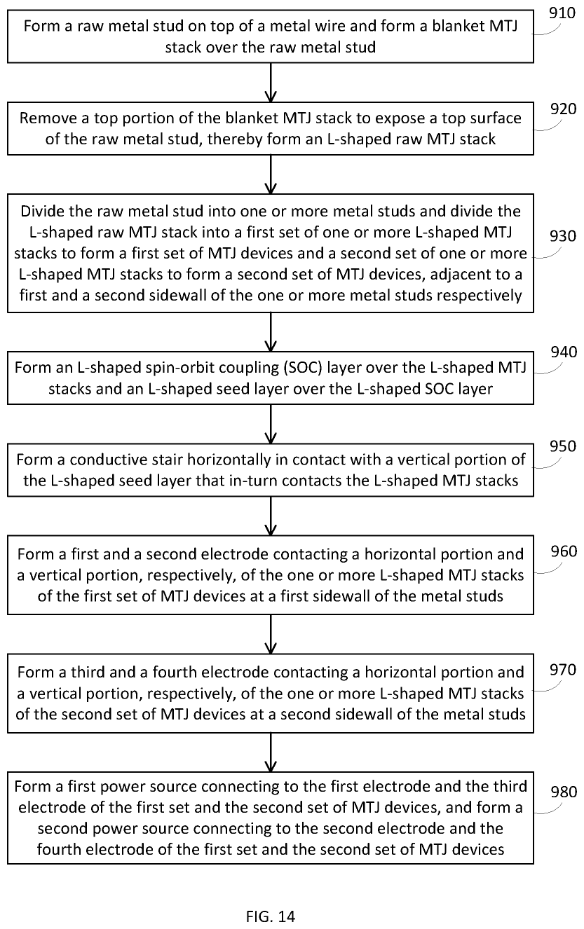

FIG. 14 is a demonstrative illustration of a flow-chart of a method of manufacturing a MTJ structure according to one embodiment of present invention. The method includes (910) forming a raw metal stud on top of a metal wire and forming a blanket MTJ stack over the raw metal stud, where the blanket MTJ stack may include a blanket free layer, a blanket tunnel barrier layer, a blanket reference layer, and a blanket performance enhancing layer; (920) removing a top portion of the blanket MTJ stack to expose a top surface of the raw metal stud thereby forming an L-shaped raw MTJ stack adjacent to sidewalls of the raw metal stud; (930) dividing the raw metal stud into one or more metal studs, dividing the L-shaped raw MTJ stack into a first set of one or more L-shaped MTJ stacks to form a first set of MTJ devices and into a second set of one or more L-shaped MTJ stacks to form a second set of MTJ devices, where the first set and the second set of the one or more L-shaped MTJ stacks are adjacent to a first and a second sidewall of the one or more metal studs respectively; (940) forming an L-shaped spin-orbit coupling (SOC) layer over the one or more L-shaped MTJ stacks and an L-shaped capping layer over the L-shaped SOC layer; (950) forming a conductive stair that is horizontally in contact with a vertical portion of the L-shaped capping layer, which in turn contacts the one or more L-shaped MTJ stacks; (960) forming a first and a second electrode contacting a horizontal portion and a vertical portion, respectively, of the one or more L-shaped MTJ stacks of the first set of MTJ devices at a first sidewall of the one or more metal studs; (970) forming a third and a fourth electrode contacting a horizontal portion and a vertical portion, respectively, of the one or more L-shaped MTJ stacks of the second set of MTJ devices at a second sidewall of the one or more metal studs; (980) forming a first power source connecting to the first electrode and the third electrode of the first set and the second set of MTJ devices, and forming a second power source connecting to the second electrode and the fourth electrode of the first set and the second set of MTJ devices.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A magnetic tunnel junction (MTJ) structure comprising:
a MTJ device, the MTJ device comprising:
an L-shaped MTJ stack, the L-shaped MTJ stack including an L-shaped reference layer; an L-shaped tunnel barrier layer conformally on the L-shaped reference layer; and
an L-shaped free layer conformally on the L-shaped tunnel barrier layer,
wherein a vertical portion of the L-shaped MTJ stack is adjacent to a sidewall of a metal stud, the metal stud being directly on top of a metal wire in a dielectric layer.

2. The MTJ structure of claim 1, wherein the L-shaped MTJ stack further includes an L-shaped performance enhancing layer with the L-shaped reference layer being conformally on the L-shaped performance enhancing layer, and the MTJ device further comprises an L-shaped spin-orbit coupling layer conformally on the L-shaped free layer and an L-shaped capping layer conformally on the L-shaped spin-orbit coupling layer.

3. The MTJ structure of claim 2, wherein the MTJ device further comprises a first electrode being in contact with a horizontal portion of the L-shaped capping layer; a conductive stair being horizontally in contact with a vertical portion of the L-shaped capping layer;
and a second electrode being in contact with the vertical portion of the L-shaped capping layer through the conductive stair.

4. The MTJ structure of claim 3, wherein the MTJ device is a first MTJ device and the metal stud is a first metal stud, further comprising a second MTJ device, the second MTJ device comprising:
an L-shaped MTJ stack that, from a bottom to a top thereof, includes an L-shaped performance enhancing layer, an L-shaped reference layer, an L-shaped tunnel barrier layer; and an L-shaped free layer; and
an L-shaped spin-orbit coupling layer and an L-shaped capping layer on top of the L-shaped MTJ stack of the second MTJ device,
wherein a vertical portion of the L-shaped MTJ stack of the second MTJ device is adjacent to a sidewall of a second metal stud, the second metal stud being horizontally aligned with the first metal stud and separated from the first metal stud by a dielectric layer.

5. The MTJ structure of claim 4, wherein the sidewall of the first metal stud is a first sidewall of the first metal stud, further comprising a third MTJ device, the third MTJ device comprising:
an L-shaped MTJ stack that, from a bottom to a top thereof, includes an L-shaped performance enhancing layer, an L-shaped reference layer, an L-shaped tunnel barrier layer; and an L-shaped free layer; and
an L-shaped spin-orbit coupling layer and an L-shaped capping layer on top of the L-shaped MTJ stack of the third MTJ device,
wherein a vertical portion of the L-shaped MTJ stack of the third MTJ device is adjacent to a second sidewall of the first metal stud, the second sidewall being opposite to the first sidewall of the first metal stud.

6. The MTJ structure of claim 5, wherein the third MTJ device further comprises a first electrode in contact with a horizontal portion of the L-shaped capping layer of the third MTJ device and a second electrode in contact with a vertical portion of the L-shaped capping layer of the third MTJ device, the first electrodes of the first MTJ device and the third MTJ device are connected to a first power source, and the second electrodes of the first MTJ device and the third MTJ device are connected to a second power source.

7. The MTJ structure of claim 4, wherein the second metal stud being directly on top of the metal wire in the dielectric layer; wherein the second MTJ device further comprises a first electrode in contact with a horizontal portion of the L-shaped capping layer of the second MTJ device and a second electrode in contact with a vertical portion of the L-shaped capping layer of the second MTJ device; and wherein the first electrodes of the first MTJ device and the second MTJ device are connected to a first power source and the second electrodes of the first MTJ device and the second MTJ device are connected to a second power source.

8. The MTJ structure of claim 4, wherein the metal wire in the dielectric layer is a first metal wire, and wherein the second metal stud is directly on top of a second metal wire in the dielectric layer, the second metal wire being separated from the first metal wire;
wherein the second MTJ device further comprises a first electrode in contact with a horizontal portion of the L-shaped capping layer of the second MTJ device and a second electrode in contact with a vertical portion of the L-shaped capping layer of the second MTJ device; and wherein the first electrode of the first MTJ device is connected to a first power source, the second electrode of the first MTJ device is connected to a second power source, the first electrode of the second MTJ device is connected to a third power source, and the second electrode of the second MTJ device is connected to a fourth power source, wherein the first, second, third, and fourth power sources are different power sources.

9. A magnetic tunnel junction (MTJ) structure comprising:
a MTJ device, the MTJ device comprising:
an L-shaped MTJ stack, the L-shaped MTJ stack including an L-shaped reference layer on an L-shaped performance enhancing layer; an L-shaped tunnel barrier layer on the L-shaped reference layer; and an L-shaped free layer on the L-shaped tunnel barrier layer,
an L-shaped spin-orbit coupling layer and an L-shaped capping layer on top of the L-shaped MTJ stack of the MTJ device;
wherein a vertical portion of the L-shaped MTJ stack is adjacent to a sidewall of a metal stud, the metal stud being directly on top of a metal wire in a dielectric layer.

10. The MTJ structure of claim 9, wherein the MTJ device further comprises a first electrode being in contact with a horizontal portion of the L-shaped capping layer; a conductive stair being horizontally in contact with a vertical portion of the L-shaped capping layer;
and a second electrode being in contact with the vertical portion of the L-shaped capping layer through the conductive stair.

11. The MTJ structure of claim 10, wherein the MTJ device is a first MTJ device and the metal stud is a first metal stud, further comprising a second MTJ device, the second MTJ device comprising:
an L-shaped MTJ stack that, from a bottom to a top thereof, includes an L-shaped performance enhancing layer, an L-shaped reference layer, an L-shaped tunnel barrier layer; and an L-shaped free layer; and
an L-shaped spin-orbit coupling layer and an L-shaped capping layer on top of the L-shaped MTJ stack of the second MTJ device,
wherein a vertical portion of the L-shaped MTJ stack of the second MTJ device is adjacent to a sidewall of a second metal stud, the second metal stud being separated from the first metal stud.

12. The MTJ structure of claim 11, wherein the second metal stud being directly on top of the metal wire in the dielectric layer.

13. The MTJ structure of claim 11, wherein the metal wire in the dielectric layer is a first metal wire, and wherein the second metal stud is directly on top of a second metal wire in the dielectric layer, the second metal wire being separated from the first metal wire.

14. The MTJ structure of claim 10, wherein the MTJ device is a first MTJ device the sidewall of the metal stud is a first sidewall of the metal stud, further comprising a second MTJ device, the second MTJ device comprising:
an L-shaped MTJ stack that, from a bottom to a top thereof, includes an L-shaped performance enhancing layer, an L-shaped reference layer, an L-shaped tunnel barrier layer; and an L-shaped free layer; and
an L-shaped spin-orbit coupling layer and an L-shaped capping layer on top of the L-shaped MTJ stack of the second MTJ device,
wherein a vertical portion of the L-shaped MTJ stack of the second MTJ device is adjacent to a second sidewall of the metal stud, the second sidewall being opposite to the first sidewall of the metal stud.

15. A method of forming a magnetic tunnel junction (MTJ) structure, the method comprising:
forming a raw metal stud on top of a metal wire, the metal wire being embedded in a dielectric layer;
forming a blanket MTJ stack over the raw metal stud and the dielectric layer;
removing a top portion of the blanket MTJ stack to expose a top surface of the raw metal stud thereby forming an L-shaped raw MTJ stack adjacent the raw metal stud;
forming a first set of one or more MTJ devices by dividing the raw metal stud into one or more metal studs and dividing the L-shaped raw MTJ stack into one or more L-shaped MTJ stacks adjacent to a first sidewall of the one or more metal studs;
forming a first electrode of the first set of one or more MTJ devices, the first electrode contacting a horizonal portion of the one or more L-shaped MTJ stacks; and
forming a second electrode of the first set of one or more MTJ devices, the second electrode contacting a vertical portion of the one or more L-shaped MTJ stacks.

16. The method of claim 15, further comprising:
forming a second set of one or more MTJ devices by dividing the L-shaped raw MTJ stack into one or more L-shaped MTJ stacks adjacent to a second sidewall of the one or more metal studs, the second sidewall being opposite to the first sidewall;
forming a third electrode of the second set of one or more MTJ devices, the third electrode contacting a horizonal portion of the one or more L-shaped MTJ stacks at the second sidewall of the one or more metal studs; and
forming a fourth electrode of the second set of one or more MTJ devices, the fourth electrode contacting a vertical portion of the one or more L-shaped MTJ stacks at the second sidewall of the one or more metal studs.

17. The method of claim 16, further comprising:
forming a first power source connecting to the first electrode of the first set of one or more MTJ devices and the third electrode of the second set of one or more MTJ devices; and
forming a second power source connecting to the second electrode of the first set of one or more MTJ devices and the fourth electrode of the second set of one or more MTJ devices.

18. The method of claim 16, further comprising:
dividing the metal wire embedded in the dielectric layer into one or more metal wires corresponding to the one or more metal studs on top thereof;
forming a first and a second power source connecting to the first and the second electrode of a first MTJ device of the first set of one or more MTJ devices; and
forming a third and a fourth power source connecting to the first and the second electrode of a second MTJ device of the first set of one or more MTJ devices,
wherein the first power source is different from the third power source and the second power source is different from the fourth power source.

19. The method of claim 15, wherein each of the L-shaped MTJ stacks includes an L-shaped free layer over an L-shaped tunnel barrier layer over an L-shaped reference layer and over an L-shaped performance enhancing layer, further comprising forming an L-shaped spin-orbit coupling (SOC) layer over each of the L-shaped MTJ stacks and an L-shaped capping layer over the L-shaped SOC layer.

20. The method of claim 19, further comprising forming a conductive stair horizontally in contact with a vertical portion of the L-shaped capping layer, wherein the second electrode is in contact with the conductive stair.
